(19) United States
(12) Patent Application Publication
(10) Pub. No.: US 2017/0135196 A1
(43) Pub. Date: May 11, 2017

(54) HEAT DISSIPATION MEMBER AND PRINTED CIRCUIT BOARD HAVING THE SAME

(71) Applicant: SAMSUNG ELECTRO-MECHANICS CO., LTD., Suwon-si (KR)

(72) Inventors: Hye Seong KIM, Suwon-si (KR); Eun Sang NA, Suwon-si (KR); Chul Soon AHN, Suwon-si (KR)

(21) Appl. No.: 15/183,116

(22) Filed: Jun. 15, 2016

(30) Foreign Application Priority Data
Nov. 10, 2015 (KR) 10-2015-0157493

(51) Int. Cl. H05K 1/02; H05K 1/03; H05K 7/20

(52) U.S. Cl. CPC H05K 1/0203; H05K 7/2039; H05K 1/0296; H05K 1/0373

(57) ABSTRACT

A heat dissipation member includes a body formed of a metal; and an epoxy resin layer formed on a surface of the body and having insulating properties. A printed circuit board includes a heat dissipation member embedded in the printed circuit board, the heat dissipation member including a body formed of a metal and an epoxy resin layer formed on a surface of the body and having insulating properties, and an insulator formed to surround the heat dissipation member.

### CROSS-REFERENCE TO RELATED APPLICATION

This application claims the benefit of priority to Korean Patent Application No. 10-2015-0157493, filed on Nov. 10, 2015 with the Korean Intellectual Property Office, the entirety of which is incorporated herein by reference.

### BACKGROUND

The present disclosure relates to a heat dissipation member and a printed circuit board having the same.

Recently, a reduction in size and weight of electronic devices has spurred a development of printed circuit boards (PCBs) equipped with electronic components such as semiconductor devices, or the like.

The electronic component may be installed on the PCB and a build-up layer may be formed for electrical connection to secure miniaturization and high density.

In a PCB with an electronic component installed thereon, heat generated by the electronic component may be released through a via serving as an interlayer signal passage. There is a limitation, however, in using only the via to release heat generated by a circuit pattern and heat generated by driving the electronic component. Heat may shorten the lifespan of the electronic component and degrade the performance thereof.

As a solution to this problem, a heat dissipation member may be embedded together with the electronic component within the PCB to facilitate heat dissipation.

The heat dissipation member may be formed of a conductive material having high thermal conductivity and may be embedded in the board in the same manner as that of the electronic component. In the course of embedding the heat dissipation member in the board, an insulator fills the surroundings of the heat dissipation member.

When heterogeneous materials between the heat dissipation member and the insulator are not properly bonded, interfaces of the heat dissipation member and the insulator may delaminate. Delamination between the heat dissipation member and the insulator may degrade the reliability of the PCB having the heat dissipation member.

As a result, a heat dissipation member having enhanced adhesion with respect to the insulator, while retaining excellent heat dissipation characteristics, is required.

### SUMMARY

An exemplary embodiment in the present disclosure provides a printed circuit board (PCB) equipped with a heat dissipation member, in which adhesion between the heat dissipation member and an insulator is enhanced to enhance reliability of the PCB.

According to an exemplary embodiment in the present disclosure, a heat dissipation member includes: an epoxy resin layer formed on a surface of a body formed of a metal to enhance adhesion between the heat dissipation member and an insulator, and a printed circuit board (PCB) having the same, the PCB having enhanced reliability.

According to another exemplary embodiment in the present disclosure, heat dissipation member comprises a body formed of a metal; and an epoxy resin layer formed on a surface of the body and having insulating properties.

According to another exemplary embodiment in the present disclosure, a printed circuit board comprises a heat dissipation member embedded in the printed circuit board, the heat dissipation member including a body formed of a metal and an epoxy resin layer formed on a surface of the body and having insulating properties; and an insulator formed to surround the heat dissipation member.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a perspective view schematically illustrating a heat dissipation member according to an exemplary embodiment in the present disclosure;

FIG. 2 is a cross-sectional view schematically illustrating a heat dissipation member according to the exemplary embodiment; and

FIG. 3 is a cross-sectional view schematically illustrating a printed circuit board (PCB) equipped with a heat dissipation member according to another exemplary embodiment in the present disclosure.

### DETAILED DESCRIPTION

Hereinafter, embodiments of the present disclosure will be described as follows with reference to the attached drawings.

The present disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on, ” “directly connected to,” or “directly coupled to” another element, there may be no other elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship relative to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” relative to other elements would then be oriented “below,” or “lower” relative to the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein describes particular embodiments only, and the present disclosure is not limited thereby. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments of the present disclosure will be described with reference to schematic views illustrating embodiments of the present disclosure. In the drawings, for example, due to manufacturing techniques and/or tolerances, modifications of the shape shown may be estimated. Thus, embodiments of the present disclosure should not be construed as being limited to the particular shapes of regions shown herein, for example, to include a change in shape results in manufacturing. The following embodiments may also be constituted by one or a combination thereof.

The contents of the present disclosure described below may have a variety of configurations and propose only a required configuration herein, but are not limited thereto.

Hereinafter, a heat dissipation member according to the present disclosure will be described.

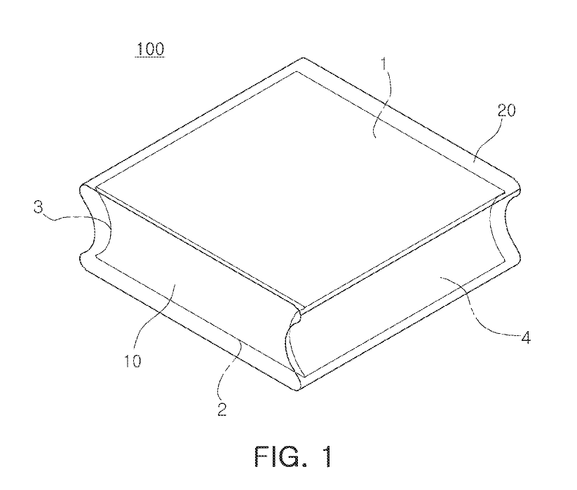

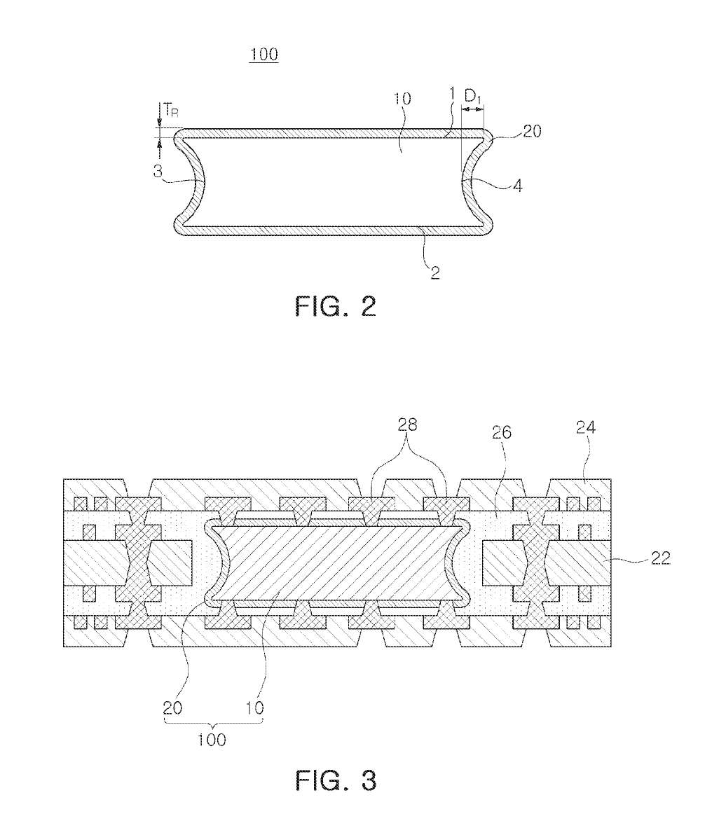

FIG. 1 is a perspective view schematically illustrating a heat dissipation member according to an exemplary embodiment in the present disclosure, and FIG. 2 is a cross-sectional view schematically illustrating a heat dissipation member according to the exemplary embodiment.

Referring to FIGS. 1 and 2, a heat dissipation member 100 according to an exemplary embodiment includes a body 10 formed of a metal and an epoxy resin layer 20 formed on a surface of the body 10 and having insulating properties.

The thickness of the body 10 may vary depending on a type of PCB, and may be, but is not limited to, 250 μm or less. A width of the body 10 may vary depending on electronic components and circuit patterns.

The body 10 may have first and second main surfaces 1 and 2 opposing each other and side surfaces 3 and 4 connecting the first and second main surfaces 1 and 2 and formed to be concave toward the interior of the body 10.

The side surfaces 3 and 4 may be a first side surface 3 and a second side surface 4, respectively, and may be formed to be concave when the body 10 is manufactured.

In detail, the body 10 including the side surfaces 3 and 4 may be formed by exposing, developing, delaminating, and etching a raw material of a metal plate having a predetermined thickness.

The etching may refer to chemical etching, and the side surfaces 3 and 4 may be formed to be concave inwardly towards a center of the body 10 in a process of being cut into a predetermined size during etching. That is, the side surfaces 3 and 4 may be configured to be bent in a direction toward each other.

In the body 10, a distance D₁ from one end of the first main surface 1 (or the second main surface 2) to a point of the first main surface 1 which meets a virtual line vertically extending from a maximally concave position of the side surface 4 (or the side surface 3) may range from 5 μm to 50 μm.

If the width is less than 5 μm, a structure in which the heat dissipation member 100 is tightly attached to an insulator is not realized when the heat dissipation member 100 is embedded in a board, and if the width exceeds 50 μm, a distance over which a resin moves to the interior of the body is lengthened, reducing adhesion between the heat dissipation member 100 and the insulator.

The body 10 may have roughness on the first and second main surfaces through a surface treatment. That is, surface roughness of the body 10 may be increased.

Since the body 10 has surface roughness, adhesion between the body 10 and the epoxy resin layer 20 formed on the surface of the body 10 may be increased. The surface treatment may be performed according to a physical or chemical method.

The heat dissipation member 100 according to the exemplary embodiment may include the epoxy resin layer 20 formed to surround the body 10 in order to increase interface adhesion between the heat dissipation member 100 and the insulator and to prevent delamination therebetween.

The epoxy resin layer 20 is formed of an epoxy resin having excellent bonding characteristics and insulating properties with respect to a metal. The epoxy resin layer 20 may be formed to cover the entire surface of the body 10 and prevent oxidation and surface contamination of the surface of the body 10.

The epoxy resin layer 20 may be formed through a dipping method, but the method of forming the epoxy resin layer 20 is not limited thereto.

A surface of the epoxy resin layer 20 may have roughness. That is, since the epoxy resin layer 20 is formed in the heat dissipation member 100, surface roughness may be controlled. The surface roughness of the epoxy resin layer 20 may be formed through a method of a plasma or corona discharge treatment.

When the surface roughness of the epoxy resin layer 20 is formed, interface adhesion with respect to the insulator within the board may be enhanced, and a delamination defect within the board may be prevented.

A thickness T_{R} of the epoxy resin layer 20 may be a thickness covering the entire surface of the body 10 with surface roughness.

As the thickness of the epoxy resin layer 20 is increased, interface adhesion with respect to the insulator of the board may be increased. If the epoxy resin layer 20 is excessively thick, however, a height of the heat dissipation member 100 to be embedded in the same board may be increased, making it difficult for the heat dissipation member 100 to be installed in the board.

Hereinafter, a PCB having a heat dissipation member of the present disclosure will be described.

FIG. 3 is a cross-sectional view schematically illustrating a printed circuit board (PCB) equipped with a heat dissipation member according to an exemplary embodiment in the present disclosure.

Referring to FIG. 3, the PCB according to an exemplary embodiment includes a heat dissipation member 100 including a body 10 embedded in a board and formed of a metal and an epoxy resin layer 20 formed on a surface of the body 10 and having insulating properties, and an insulator 26 formed to surround the heat dissipation member 100.

The heat dissipation member 100 may be embedded in the PCB and may serve to dissipate heat generated by an electronic component surface-mounted in the PCB through the PCB.

The heat dissipation member 100 may be mounted within a cavity formed in a core part 22.

Circuit patterns 24 may be formed on upper and lower surfaces of the core part 22, and may be insulated by an insulating portion (not shown).

A thickness of the body 10 may vary according to a type of the PCB and may be, but is not limited to, 250 μm or less. A width of the body 10 may vary according to electronic components or circuit patterns.

The body 10 may be formed of a conductive metal, such as copper (Cu).

The body 10 may have first and second main surfaces 1 and 2 opposing each other and side surfaces 3 and 4 connecting the first and second main surfaces 1 and 2 and formed to be concave toward the interior of the body 10.

The side surfaces 3 and 4 may be a first side surface 3 and a second side surface 4, respectively, and may be formed to be concave when the body 10 is manufactured.

In the body 10, a distance D₁ from one end of the first main surface 1 (or the second main surface 2) to a point of the first main surface 1 which meets a virtual line vertically extending from a maximally concave position of the side surface 4 (or the side surface 3) may range from 5 μm to 50 μm.

If the width is less than 5 μm, a structure in which the heat dissipation member 100 is tightly attached to an insulator is not realized when the heat dissipation member 100 is installed in a board, and if the width exceeds 50 μm, a distance over which a resin moves to the interior of the body is lengthened, reducing adhesion between the heat dissipation member 100 and the insulator.

The first and second main surfaces 1 and 2 of the body 10 may have roughness through a surface treatment. That is, surface roughness of the first and second main surfaces 1 and 2 of the body 10 may be increased.

Since the first and second main surfaces 1 and 2 of the body 10 have roughness, adhesion between the body 10 and the epoxy resin layer 20 formed on the surface of the body 10 may be increased. The surface treatment may be performed according to a physical or chemical method.

The insulator 26 may include a resin and an inorganic filler.

The resin may be one selected from among a phenol resin, a urea resin, a melamine resin, an alkyd resin, a furan resin, a silicone resin, and an epoxy resin.

The inorganic filler may be at least one of glass, silica, and ceramics.

The insulator 26 may include a 30 wt % to 80 wt % of inorganic filler, based on a total weight of the insulator, but the content of the inorganic filler may vary according to conditions of a board.

The insulator 26 may serve to fix an electronic component or the heat dissipation member 100 embedded in the board and insulate the electronic component or the heat dissipation member 100 from the exterior.

The resin of the insulator 26 may have flowability at a certain temperature when pressure is applied thereto during a board manufacturing process, and thereafter, when the resin of the insulator 26 is cured, it may adhere to the surface of the body 10, formed of a metal, of the heat dissipation member 100. When heat is generated and cooling repeatedly occurs in the board environment, however, the insulator 26 may become deformed due to the repeated contraction and expansion of the resin, which may reduce adhesion in the interface between the insulator 26 and the heat dissipation member 100 to cause delamination.

In order to solve this problem, surface roughness of the body 10 of the heat dissipation member 100 may be increased to enhance adhesion between the heat dissipation member 100 and the insulator 26. The surface roughness may have partial variations, however, allowing delamination to occur.

The inorganic filler of the insulator 26 is free from such a behavior of contraction and expansion at a corresponding temperature and pressure. That is, the inorganic filler may flow within the resin when the resin is flowable, and may be fixed in the resin when the resin is cured.

However, the inorganic filler included in the insulator 26 does not adhere to and is not bonded to the surface of the heat dissipation member 100, so it may reduce interface adhesion between the insulator 26 and the heat dissipation member 100. Thus, as the content of the inorganic filler of the insulator 26 is increased, the likelihood of delamination may be increased within the board.

The heat dissipation member 100 according to the present disclosure includes the epoxy resin layer 20 formed on the surface of the body 10 and having insulating properties, and thus interface adhesion between the heat dissipation member 100 and the insulator 26 may be increased and a delamination defect may be prevented.

The epoxy resin layer 20 may be formed using a dipping method, but a method of forming the epoxy resin layer is not limited thereto.

The epoxy resin layer 20 is formed of an epoxy resin having excellent adhesion with respect to a metal. The epoxy resin layer 20 may cover an entirety of the surface of the body 10 and prevent oxidation and contamination of the surface of the body 10.

The epoxy resin layer 20 may be formed between the body 10 and the insulator 26.

The epoxy resin layer 20 may be formed of the same material as that of the resin included in the insulator 26 of the board, and thus interface adhesion with respect to the insulator 26 may be enhanced.

That is, since the epoxy resin layer 20 of the heat dissipation member 100 is formed of the same material as that of the resin included in the insulator 26, interface adhesion between the heat dissipation member 100 and the insulator 26 may be enhanced, and occurrence of delamination may be prevented.

A surface of the epoxy resin layer 20 may have roughness. That is, since the epoxy resin layer 20 is formed in the heat dissipation member 100, surface roughness may be controlled.

The surface roughness of the epoxy resin layer 20 may be formed through a method of a plasma or corona discharge treatment.

When the surface roughness of the epoxy resin layer 20 is formed, interface adhesion with respect to the insulator within the board may be enhanced, and a delamination defect within the board may be prevented.

A thickness T_{R} of the epoxy resin layer 20 may be a thickness covering the entire surface of the body 10 with surface roughness.

As the thickness of the epoxy resin layer 20 is increased, interface adhesion with respect to the insulator of the board may be increased, but if the epoxy resin layer 20 is excessively thick, a height of the heat dissipation member 100 to be embedded in the same board may be increased, making it difficult for the heat dissipation member 100 to be mounted on the board.

The circuit patterns 24 are formed on the insulator 26. The circuit patterns 24 formed on upper and lower surfaces of the PCB are connected to each other through the via 28.

The via 28 may be formed by filling the interior of a via hole (not shown) with a solder resist.

The via 28 may penetrate through the insulator 26 to electrically connect the circuit pattern 24 formed on the board and the heat dissipation member 100.

The via 28 may be electrically connected to the body 10 through the epoxy resin layer 20 of the heat dissipation member 100. Since the via 28 and the body 10 are directly in contact with each other, a heat dissipation effect of dissipating heat of the PCB may be secured.

The via 28 connected to the heat dissipation member 100 may be a passage conducting heat generated within the board.

As set forth above, according to exemplary embodiments of the present disclosure, the heat dissipation member may have enhanced adhesion with respect to the insulator, and thus reliability of the PCB may be enhanced.

While exemplary embodiments have been shown and described above, it will be apparent to those skilled in the art that modifications and variations could be made without departing from the scope of the present invention as defined by the appended claims.

What is claimed is:

1. A heat dissipation member comprising:
a body formed of a metal; and
an epoxy resin layer formed on a surface of the body and having insulating properties.

2. The heat dissipation member of claim 1, wherein the body is formed of copper (Cu).

3. The heat dissipation member of claim 1, wherein the body includes first and second main surfaces opposing each other and side surfaces connecting the first and second main surfaces and formed to be concave inwardly towards a center of the body.

4. The heat dissipation member of claim 3, wherein a distance from one end of the first main surface or the second main surface to a point of the first main surface or the second main surface which meets a virtual line vertically extending from a maximally concave position of either of the side surfaces ranges from 5 μm to 50 μm.

5. The heat dissipation member of claim 3, wherein the first and second main surfaces of the body have roughness.

6. The heat dissipation member of claim 1, wherein a surface of the epoxy resin layer has roughness.

7. The heat dissipation member of claim 1, wherein the epoxy resin layer covers an entirety of the surface of the body.

8. A printed circuit board comprising:
a heat dissipation member embedded in the printed circuit board, the heat dissipation member including a body formed of a metal and an epoxy resin layer formed on a surface of the body and having insulating properties; and
an insulator formed to surround the heat dissipation member.

9. The printed circuit board of claim 8, wherein the body includes first and second main surfaces opposing each other and side surfaces connecting the first and second main surfaces and formed to be concave inwardly toward a center of the body.

10. The printed circuit board of claim 9, wherein a distance from one end of the first main surface or the second main surface to a point of the first main surface or the second main surface which meets a virtual line vertically extending from a maximally concave position of either of the side surfaces ranges from 5 μm to 50 μm.

11. The printed circuit board of claim 9, wherein the first and second main surfaces of the body have roughness.

12. The printed circuit board of claim 8, wherein the epoxy resin layer covers an entirety of the surface of the body.

13. The printed circuit board of claim 8, wherein a surface of the epoxy resin layer has roughness.

14. The printed circuit board of claim 8, wherein the insulator includes a resin and an inorganic filler.

15. The printed circuit board of claim 14, wherein the insulator is between 30 wt % to 80 wt % inorganic filler, based on a total weight of the insulator.

16. The printed circuit board of claim 14, wherein the resin is selected from the group consisting of a phenol resin, a urea resin, a melamine resin, an alkyd resin, a furan resin, a silicone resin, and an epoxy resin.

17. The printed circuit board of claim 14, wherein the inorganic filler includes at least one of glass, silica, and ceramics.

18. The printed circuit board of claim 14, wherein the epoxy resin layer and the resin are formed of the same material.

19. The printed circuit board of claim 8, further comprising a via electrically connecting a circuit pattern of the printed circuit board and the heat dissipation member through the insulator.

20. The printed circuit board of claim 15, wherein the via is connected to the body through the epoxy resin layer.
